(19) United States
(12) Patent Application Publication
(10) Pub. No.: US 2019/0067844 A1
(43) Pub. Date: Feb. 28, 2019

(54) CONNECTOR, DISPLAY DEVICE INCLUDING THE SAME, AND METHOD OF MANUFACTURING THE DISPLAY DEVICE

(71) Applicant: Samsung Display Co., Ltd., Yongin-Si (KR)

(72) Inventors: Jeonghun GO, Asan-si (KR); Sunkyu SANG, Suwon-si (KR); Jungmi YUN, Hwaseong-si (KR)

(21) Appl. No.: 15/918,285

(22) Filed: Mar. 12, 2018

(30) Foreign Application Priority Data
Aug. 25, 2017 (KR) 10-2017-0108224

(51) Int. Cl. H01R 12/52; H01R 43/02; H05K 1/14; H05K 1/11; H05K 3/36

(52) U.S. Cl. CPC H01R 12/52; H01R 43/0256; H05K 1/144; H05K 1/111; H05K 2203/0278; H05K 1/142; H05K 2201/042; H05K 2201/1031; H05K 2201/10128; H05K 3/368

(57) ABSTRACT

A display device includes a display panel configured to display an image, a first circuit board electrically connected to the display panel and including a first connecting pad part, a second circuit board electrically connected to the display panel and including a second connecting pad part overlapping the first connecting pad part, and a connector disposed between the first circuit board and the second circuit board to electrically connect the first connecting pad part to the second connecting pad part. The connector includes a base plate; and a pad part including a first pad surface exposed from one surface of the base plate and a second pad surface exposed from the other surface of the base plate, and the first pad surface and the second pad surface overlap each other in a plan view.

### CROSS-REFERENCE TO RELATED APPLICATIONS

This U.S. non-provisional patent application claims priority under 35 U.S.C. § 119 to Korean Patent Application No. 10-2017-0108224, filed on Aug. 25, 2017, the entire contents of which are hereby incorporated by reference.

### BACKGROUND

The present disclosure herein relates to a connector, a display device including the same, and a method of manufacturing the same, and more particularly, to a connector with costs reduced, a display device including the same, and a method of manufacturing the same with a process simplified.

Various display devices providing a multimedia service, e.g., a television, a mobile phone, a navigation unit, a computer monitor, and a game console, are being developed.

The display devices include a display panel for displaying an image and a controller generating various signals for driving the display panel. The controller may be realized by various circuits and electronic elements on a printed circuit board.

As the display panel has a large size and a high resolution, an amount of data of a signal to be processed in the controller increases, and, accordingly, the size of the circuits and the number of the elements for realizing the controller also increase.

Accordingly, the large-sized display panel uses multiple printed circuit boards. For electrically connecting the multiple printed circuit boards to each other, a connector for each board and an additional member for connecting the same are required.

### SUMMARY

The present disclosure provides a connector with costs reduced. The present disclosure also provides a connector for electrically connecting divided printed circuit boards used for a large-sized display panel.

An embodiment of the inventive concept provides a display device including: a display panel configured to display an image; a first circuit board electrically connected to the display panel and including a first connecting pad part; a second circuit board electrically connected to the display panel and including a second connecting pad part overlapping the first connecting pad part; and a connector disposed between the first circuit board and the second circuit board to electrically connect the first connecting pad part to the second connecting pad part.

The connector includes: a base plate; and a pad part including a first pad surface exposed from one surface of the base plate and a second pad surface exposed from the other surface of the base plate, and the first pad surface and the second pad surface overlap each other in a plan view.

In an embodiment, the pad part may pass through the one surface and the other surface of the base plate and include a pad.

In an embodiment, the first pad surface and the one surface of the base plate may define the same plane, and the second pad surface and the other surface of the base plate may define the same plane.

In an embodiment, the first pad surface may protrude from the one surface of the base plate in a thickness direction of the base plate, and the second pad surface may protrude from the one other surface of the base plate in the thickness direction of the base plate.

In an embodiment, the base plate may include a material that is rigid and has a melting point greater than that of the pad, and the pad may include a material having a melting point less than that of each of the first connecting pad part and the second connecting pad part.

In an embodiment, each of a first circuit board and a second circuit board may include: a first circuit layer; a second circuit layer disposed on a rear surface of the first circuit layer; an insulation layer disposed between the first circuit layer and the second circuit layer; a first protective layer disposed on a front surface of the first circuit layer; and a second protective layer disposed on a rear surface of the second circuit layer.

In an embodiment, each of the first connecting pad part and the second connecting pad part is disposed on the first protective layer and electrically connected to the first circuit layer or the second circuit layer.

In an embodiment, each of the first connecting pad part and the second connecting pad part may be disposed on the same layer as the first circuit layer or the second circuit layer and exposed from the first protective layer.

In an embodiment, each of the first circuit board and the second circuit board may include a connection area in which each of the first connecting pad part and the second connecting pad part is disposed and a circuit area disposed adjacent to the connection area, the connection area has a thickness less than that of the circuit area, and a sum of a thickness of the connection area of the first circuit board, a thickness of the connection area of the second circuit board, and a thickness of the connector is equal to or less than a thickness of each of the circuit areas.

In an embodiment of the inventive concept, a connector includes: a base plate; and a pad part including a first pad surface exposed from one surface of the base plate and a second pad surface exposed from the other surface of the base plate, and the first pad surface and the second pad surface overlap each other in a plan view.

In an embodiment, the pad part may include a pad passing through one surface and the other surface of the base plate.

In an embodiment, the first pad surface and the one surface of the base plate may define the same plane, and the second pad surface and the other surface of the base plate may define the same plane.

In an embodiment, the first pad surface may protrude from the one surface of the base plate in a thickness direction of the base plate, and the second pad surface may protrude from the other surface of the base plate in the thickness direction of the base plate.

In an embodiment, the pad part may include a pad, and the pad may include: a first pad disposed on the one surface of the base plate to include the first pad surface; and a second pad disposed on the other surface of the base plate to include the second pad surface.

In an embodiment, the connector may further include a passing-through pad portion connecting the first and second pads while overlapping the first and second pads in a plan view.

In an embodiment, the base plate may be flexible, the base plate may include a material having a melting point less than that of each of the first and second pads, and each of the first and second pads may include a material having a melting point less than that of copper (Cu).

In an embodiment, the base plate may be rigid, the base plate may include a material having a melting point greater than that of each of the first and second pad surfaces, and each of the first and second pad surfaces may include a material having a melting point less than that of copper (Cu).

In an embodiment of the inventive concept, a method of manufacturing a display device includes: providing a first circuit board including a first connecting pad part; providing a second circuit board including a second connecting pad part configured to overlap the first connecting pad part; providing a connector configured to electrically connect the first connecting pad part to the second connecting pad part and disposed between the first and second circuit boards; and performing thermal compression on the first and second connecting pad parts and the connector so that the first and second circuit boards are electrically connected to each other. The connector includes: a base plate; and a pad part including a first pad surface exposed from one surface of the base plate and a second pad surface exposed from the other surface of the base plate, and the first and second pad surfaces overlap each other in a plan view.

In an embodiment, when the first and second circuit boards are connected to each other, the base plate may be remained between the pad parts in an alternating manner

In an embodiment, when the first and second circuit boards are connected to each other, heat greater than a melting point of the base plate may be provided.

### BRIEF DESCRIPTION OF DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram of a display device according to an embodiment of the inventive concept;

FIG. 2 is a schematic plan view of a display device according to an embodiment of the inventive concept;

FIG. 3A is a cross-sectional view taken along line I-I′ in FIG. 1;

FIG. 3B is a cross-sectional view taken along line II-II′ in FIG. 1;

FIGS. 4A, 4B and 4C are cross-sectional views of a printed circuit board according to an embodiment of the inventive concept;

FIGS. 5A and 5B are cross-sectional views illustrating a state in which printed circuit boards are electrically connected according to an embodiment of the inventive concept;

FIGS. 6A and 6B are plan views of a connector according to an embodiment of the inventive concept;

FIGS. 7A and 7B are cross-sectional views illustrating a connector having a pad part passing through a base plate according to an embodiment of the inventive concept;

FIG. 8 is a cross-sectional view illustrating a connector having a passing-through pad according to an embodiment of the inventive concept;

FIG. 9 is a cross-sectional view illustrating a connector having a pad disposed on one surface and the other surface of a base plate according to an embodiment of the inventive concept;

FIG. 10 is a flowchart of a method for manufacturing a display device according to an embodiment of the inventive concept;

FIGS. 11A to 11B are cross-sectional views illustrating a step of performing thermal compression on printed circuit boards according to an embodiment of the inventive concept; and

FIGS. 12A, 12B and 12C are cross-sectional views illustrating a step of performing thermal compression on printed circuit boards according to an embodiment of the inventive concept.

### DETAILED DESCRIPTION

Since the inventive concept may be embodied in different forms, embodiments in the detailed description will be described with sectional views of the present disclosure. However, this does not limit the present disclosure within specific embodiments and it should be understood that the present disclosure covers all the modifications, equivalents, and replacements within the idea and technical scope of the present disclosure.

Like reference numerals refer to like elements throughout. In the figures, the dimensions of layers and regions are exaggerated for clarity of illustration. It will be understood that although the terms of first and second are used herein to describe various elements, these elements should not be limited by these terms. Terms are only used to distinguish one component from other components. For example, a first element referred to as a first element in one embodiment can be referred to as a second element in another embodiment. The terms of a singular form may include plural forms unless referred to the contrary.

The meaning of “include,” “comprise,” “including,” or “comprising,” specifies features, integers, steps, operations, elements, components or combinations thereof listed in the specification but does not exclude other features, integers, steps, operations, elements, components or combinations thereof.

Exemplary embodiments of the inventive concept will be described below in more detail with reference to the accompanying drawings.

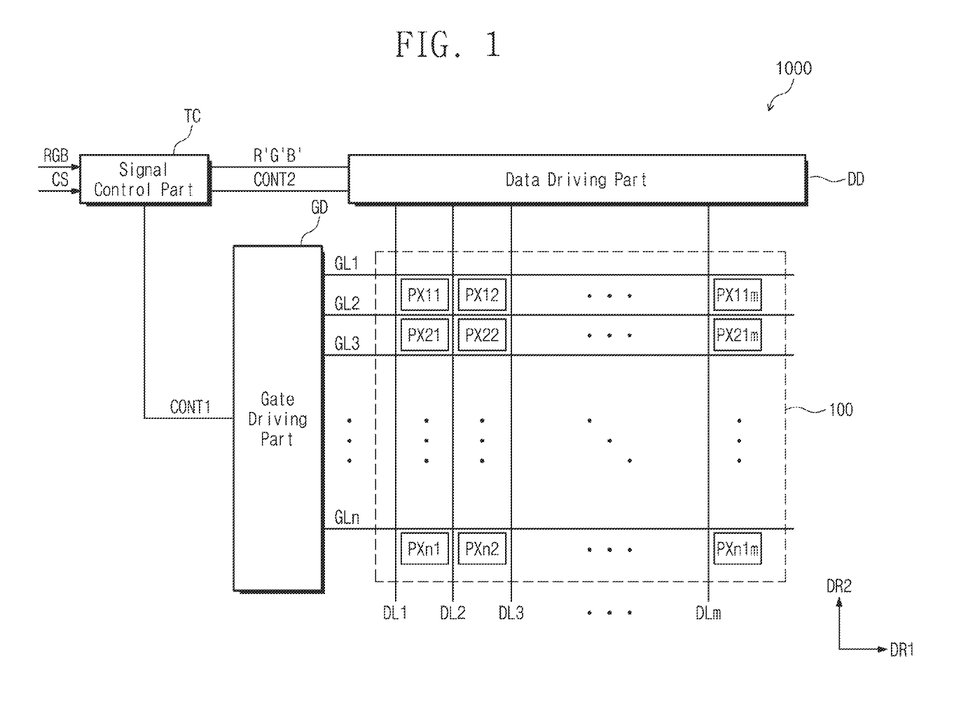

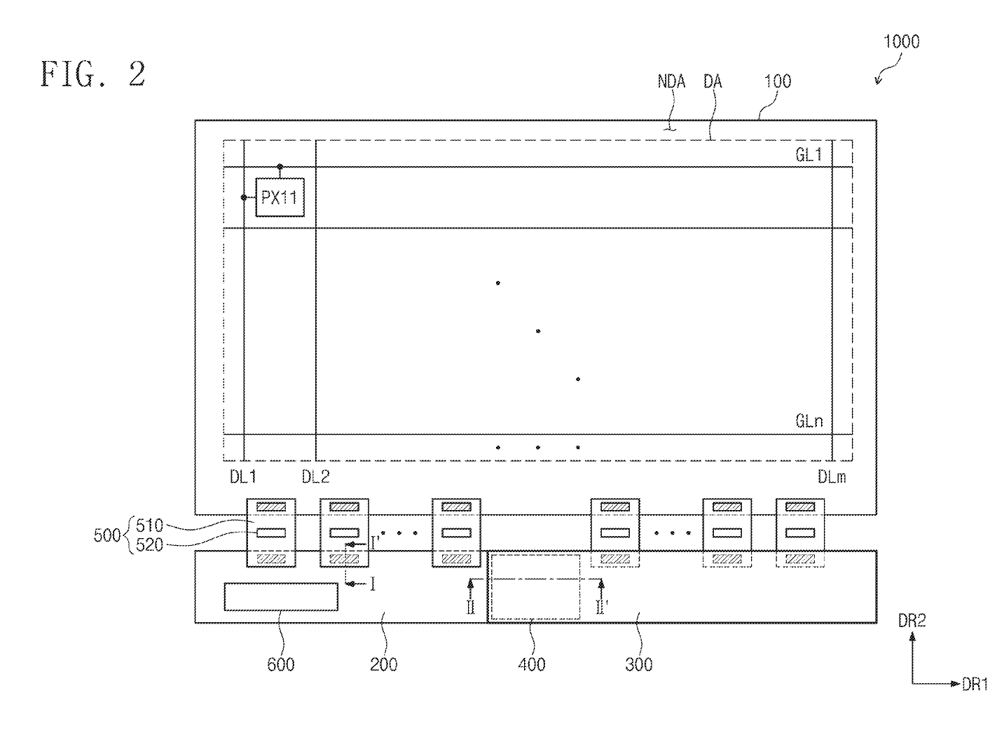

FIG. 1 is a block diagram of a display device according to an embodiment of the inventive concept. FIG. 2 is a schematic plan view of a display device according to an embodiment of the inventive concept. The display device will be described with reference to FIGS. 1 and 2.

A display device 1000 according to an embodiment of the inventive concept may include a display panel 100, a first printed circuit board 200, a second printed circuit board 300, a connector 400, an output flexible printed circuit board 500, and a controller 600

The display device 1000 may be activated by receiving an electric signal and display an image.

A user may receive information through the image displayed on the display device 1000.

Referring to FIG. 1, the display device 1000 may include a signal control part TC, a gate driving part GD, a data driving part DD, and the display panel 100, which are electrically connected to each other.

The signal control part TC receives input image signals RGB and converts the input image signals RGB into an image data R′G′B′ suitable to an operation of the display panel 100. Also, the signal control part TC receives all sorts of control signals CS such as, e.g., a vertical synchronizing signal, a horizontal synchronizing signal, a main clock signal, and an enable signal and outputs first and second control signals CONT1 and CONT2.

The first control signal CONT1 includes a vertical start signal for starting an operation of the gate driving part GD, a gate clock signal for determining a time for outputting a gate voltage, and an output enable signal for determining an on-pulse width of the gate voltage.

The second control signal CONT2 includes a horizontal start signal for starting an operation of the data driving part DD, a reverse signal for reversing polarities of the data signals, and an output commanding signal for determining a time for outputting the data voltages.

The gate driving part GD outputs gate signals to a plurality of gate lines GL1 to GLn in response to the first control signal CONT1.

The data driving part DD receives the second control signal CONT2 and the image data R′G′B′. The data driving part DD converts the image data R′G′B′ into data voltages to provide the converted data voltages to a plurality of data lines DL1 to DLm.

The display panel 100 includes a plurality of signal wires and a plurality of pixels PX11 to PXnm that are connected to the plurality of signal wires. The plurality of signal wires include a plurality of gate lines GL1 to GLn and a plurality of data lines DL1 to DLm.

The plurality of gate lines GL1 to GLn extend in a first direction DR1 and are arranged in a second direction DR2. The plurality of gate lines GL1 to GLn may electrically connect the gate driving part GD to the display panel 100. The plurality of gate lines GL1 to GLn may be respectively connected to the plurality of pixels PX11 to PXnm and transmit a gate signal to the corresponding pixels.

The plurality of data lines DL1 to DLm extend in the second direction DR2 and are arranged in the first direction DR1. The plurality of data lines DL1 to DLm insulatively cross the plurality of gate lines GL1 to GLn. The plurality of data lines DL1 to DLm may receive data voltages converted by the data driving part DD. The plurality of data lines DL1 to DLm are respectively connected to the plurality of pixels PX11 to PXnm

Meanwhile, although not shown, the plurality of signal wires may further include a plurality of common lines corresponding to the plurality of gate lines GL1 to GLn.

Referring to FIG. 2, the display panel 100 may be divided into a display area DA and a non-display area NDA. The plurality of pixels PX11 to PXnm may be arranged on the display area DA. The plurality of pixels PX11 to PXnm are activated by receiving electric signal to realize an image. Accordingly, the display area DA may be an area on which the image is displayed. The non-display area NDA is disposed around the display area DA.

The plurality of pixels PX11 to PXnm may be arranged in a matrix configuration. The plurality of pixels PX11 to PXnm are respectively connected to the plurality of gate lines GL1 to GLn and the plurality of data lines DL1 to DLm in a corresponding manner

FIG. 2 exemplarily illustrates one pixel PX11 for ease of description. The pixel PX11 may have characteristics that are applied to each of the plurality of pixels PX11 to PXnm

The pixel PX11 is an element for displaying a unit image, and the number of pixel PX11 provided in the display panel 100 may affect on a resolution of the display panel 100.

The pixel 11 includes a display element and a pixel circuit connected to the display element to drive the display element. The pixel circuit may include a thin-film transistor and a capacitor connected to the thin-film transistor to maintain a signal. The display element may include a liquid crystal cell or an organic light emitting diode (OLED), an electrophoretic element, and an electrowetting element. The liquid crystal cell includes a pixel electrode, a common electrode, and a liquid crystal disposed between the pixel electrode and the common electrode. The OLED includes an anode electrode, a cathode electrode, and an organic thin-film layer provided between the anode electrode and the cathode electrode. The organic thin-film layer may have a structure in which a hole transporting layer, an organic light emitting layer, and an electron transporting layer are laminated and further include a hole injection layer and an electron injection layer.

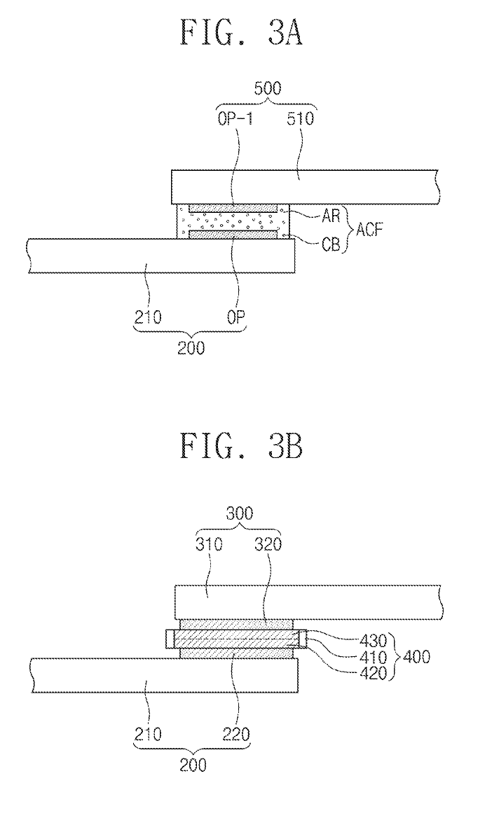

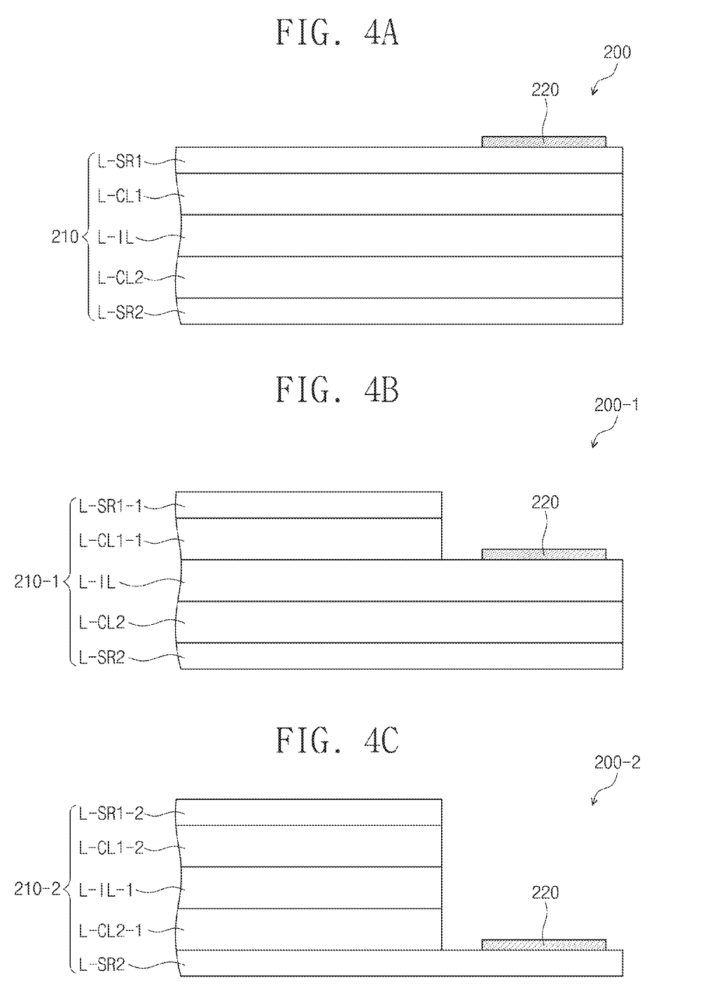

The first printed circuit board 200 may be disposed at one side of the display panel 100. The first printed circuit board 200 may include a first output pad part OP disposed at one side thereof. The first output pad part OP (refer to FIG. 3A) may be electrically connected to the display panel 100 through the output flexible printed circuit board 500. The controller 600 may be mounted in a chip type at one side of the first printed circuit board 200.

The controller 600 may include the above-described signal control part TC.

The second printed circuit board 300 may be disposed at one side of the display panel 100. The second printed circuit board 300 may include a first output pad part OP disposed at one side thereof. The first output pad part OP may be electrically connected to the display panel 100 through the output flexible printed circuit board 500.

The second printed circuit board 300 may be disposed at the same side, at which the first printed circuit board 200 is disposed, of the display panel 100.

The second printed circuit board 300 has at least a portion overlapping the first printed circuit board 200 in a plan view.

The connector 400 may be disposed on the portion in which the first printed circuit board 200 and the second printed circuit board 300 overlap each other. The connector 400 electrically connects the first printed circuit board 200 to the second printed circuit board 300. In the embodiment, the second printed circuit board 300 covers the entire connector 400. Accordingly, the connector 400 is not seen in a plan view, the connector 400 is expressed in a dotted line in FIG. 2. Hereinafter, the connector 400 will be described later.

The output flexible printed circuit board 500 may include a flexible board 510, a driving chip 520, and a second output pad part OP-1 (refer to FIG. 3A). The output flexible printed circuit board 500 may be provided in plurality and arranged in one direction. The plurality of output flexible printed circuit boards may be disposed at one side of the first printed circuit board 200 and the second printed circuit board 300, which overlap each other, and electrically connect the first printed circuit board 200 and the second printed circuit board 300 to the display panel 100. The output flexible printed circuit board 500 may be electrically connected through the second output pad part OP-1 (refer to FIG. 3A) corresponding to the first output pad part OP of the first printed circuit board 200 and the second printed circuit board 300. Although not shown, the display panel 100 may also include a pad part corresponding to the output flexible printed circuit board 500 and be electrically connected therethrough.

The flexible board 510 may have flexibility and include a plurality of circuit wires. Accordingly, the flexible board 510 may have various shapes in correspondence to shapes of the printed circuit boards.

The driving chip 520 may be mounted on the flexible board 510 in a form of a chip on film (COF). The driving chip 520 may include a data driving part DD or a gate driving part GD.

FIGS. 3A and 3B are cross-sectional views taken along lines I-I′ and II-II′ in FIG. 1. FIG. 3A illustrates connection between the first printed circuit board 200 and the output flexible printed circuit board 500, and FIG. 3B illustrates connection between the first printed circuit board 200 and the second printed circuit board 300.

The first printed circuit board 200 may include a first board 210, a first connecting pad part 220, and a first output pad part OP.

The first board 210 may be a support layer including a plurality of first output pad parts arranged along one side of the first board 210 which is adjacent to the display panel 100. Although not shown, the first board 210 may include a plurality of circuit layers. The first board 210 may be rigid.

Referring to FIG. 3A, the first output pad part OP is disposed on the first board 210. The first output pad part OP may be disposed on an area of the first board 210, which is adjacent to the display panel 100 (refer to FIG. 2). The first output pad part OP may be made of a conductive material. For example, the first output pad part OP may be made of a metal layer such as gold, silver, aluminum, and copper or provided as a transparent conductive oxide layer such as indium tin oxide (ITO).

The first output pad part OP may be connected to the output flexible printed circuit board 500. The first output pad part OP may be electrically connected to the second output pad part OP-1 of the output flexible printed circuit board 500.

The second output pad part OP-1 may be disposed on the plurality of output flexible printed circuit boards in correspondence to the first output pad part OP. For example, the second output pad part OP-1 may be disposed to overlap the first output pad part OP in a plan view. The second output pad part OP-1 may be made of a conductive material. However, an embodiment of the inventive concept is not limited thereto. For example, the second output pad part OP-1 may include the same material as that of the first output pad part OP.

Referring to FIG. 3A, the first output pad part OP and the second output pad part OP-1 may be electrically connected through an anisotropic conductive film (ACF). Although the first output pad part OP and the second output pad part OP-1 are not in direct contact each other, as the first output pad part OP and the second output pad part OP-1 are electrically coupled through the anisotropic conductive film ACF, the first printed circuit board 200 and the output flexible printed circuit board 500 may be electrically connected to each other.

The anisotropic conductive film ACF may electrically connect the first output pad part OP to the second output pad part OP-1 through a thermal compression process. The anisotropic conductive film ACF may include an adhesive resin AR and a plurality of conductive balls CB distributed in the adhesive resin AR. The adhesive resin AR fixes the plurality of conductive balls CB in a predetermined area and physically couples the first printed circuit board 200 to the output flexible printed circuit board 500. The plurality of conductive balls CB electrically couple the first printed circuit board 200 to the output flexible printed circuit board 500.

However, an embodiment of the inventive concept is not limited to the electric connection between the first and second printed circuit board 200 and 300 and the display panel 100 through the anisotropic conductive film ACF. For example, the first output pad part OP and the second output pad part OP-1 may be electrically connected to each other by a plurality of soldering portions disposed between the first output pad part OP and the second output pad part OP-1.

Meanwhile, although not shown, the second printed circuit board 300 and the output flexible printed circuit board 500 may be electrically connected through the same method as that between the first printed circuit board 200 and the output flexible printed circuit board 500. Hereinafter, redundant description will be omitted.

The first connecting pad part 220 is disposed on the first board 210. The first connecting pad part 220 may be disposed on an area in which the first printed circuit board 200 overlaps the second printed circuit board 300. The first connecting pad part 220 may be made of a conductive material. For example, the first connecting pad part 220 may include the same material as that of the first output pad part OP.

The first connecting pad part 220 may be connected to the second printed circuit board 300. The second printed circuit board 300 may include a second board 310 and a second connecting pad part 320.

The second board 310 may be a support layer including the second connecting pad part 320 that is disposed on an area in which the first board 210 overlaps the second board 310. Although not shown, the second board 310 may include a plurality of circuit layers. The second board 310 may be rigid.

The second connecting pad part 320 is disposed on the second board 310. The second connecting pad part 320 may be disposed on an area in which the first printed circuit board 200 overlaps the second printed circuit board 300. The second connecting pad part 320 may be made of a conductive material. For example, the second connecting pad part 320 may include the same material as that of the first output pad part OP.

The first printed circuit board 200 and the second printed circuit board 300 may be electrically connected through the connector 400 disposed between the first connecting pad part 220 and the second connecting pad part 320.

The connector 400 may include a base plate 410, a first pad part 420, and a second pad part 430. The connector 400 may be electrically connected by being disposed between the first connecting pad part 220 and the second connecting pad part 320.

The base plate 410 may be made of an insulating material capable of mounting the first and second pad parts 420 and 430.

The first pad part 420 is disposed on one surface of the base plate 410. The first pad part 420 may overlap the first connecting pad part 220. The first pad part 420 may overlap the first connecting pad part 220 so that the first pad part 420 is electrically connected to the first connecting pad part 220. The first pad part 420 may be made of a conductive material. However, an embodiment of the inventive concept is not limited thereto. For example, the first pad part 420 may include the same material as that of the first output pad part OP.

The first pad part 420 may include a first pad surface. The first pad surface may be a surface of the connector 400, which is connected to the first printed circuit board 200. In the embodiment, the first pad surface may be defined on a rear surface of a first pad, which faces the first printed circuit board 200, of the first pad part 420.

The second pad part 430 may be disposed on the other surface of the base plate 410. The second pad part 430 may overlap the second connecting pad part 320. The second pad part 430 may overlap the second connecting pad part 320 so that the second pad part 430 is electrically connected to the second connecting pad part 320. The second pad part 430 may be made of a conductive material. However, an embodiment of the inventive concept is not limited thereto. For example, the second pad part 430 may include the same material as that of the first output pad part OP.

The second pad part 430 may include a second pad surface. The second pad surface may be a surface of the connector 400, which is connected to the second printed circuit board 300. In the embodiment, the second pad surface may be defined on a top surface of a second pad, which faces the second printed circuit board 300, of the second pad part 430.

In the embodiment, the first pad part 420 and the second pad part 430 may pass through the base plate 410 and be connected to each other. The first pad part 420 and the second pad part 430 may form a flat surface with the base plate 410. Accordingly, the first pad surface may provide the same plane as a rear surface of the base plate 410, and the second pad surface may provide the same plane as a front surface of the base plate 410.

The first connecting pad part 220 and the first pad part 420 disposed on one surface of the base plate 410 may overlap each other in a plan view and be electrically connected to each other. Also, the second connecting pad part 320 and the second pad part 430 disposed on the other surface of the base plate 410 may overlap each other in a plan view and be electrically connected to each other.

Accordingly, the connector 400 overlaps the first and second printed circuit boards 200 and 300 and is disposed therebetween. The embodiment may include an embodiment in which the first and second printed circuit boards 200 and 300 are connected to each other by the connector 400 disposed therebetween.

According to an embodiment of the inventive concept, the connector 400 connecting the printed circuit board to each other may include an embodiment different from the connector between the output flexible printed circuit board 500 and the printed circuit boards. Accordingly, electric coupling between the printed circuit boards that are relatively rigid than the output flexible printed circuit board may be more stably maintained. Also, since an additional connector for connection between the printed circuit boards and a flexible film for connection between the printed circuit boards are unnecessary, manufacturing costs may be reduced. Also, since each of the connecting pad parts of the printed circuit boards is directly connected, the electric characteristics thereof may improve, and as an additional connector and a flexible film are removed, the costs may be reduced, and manufacturing process may be simplified.

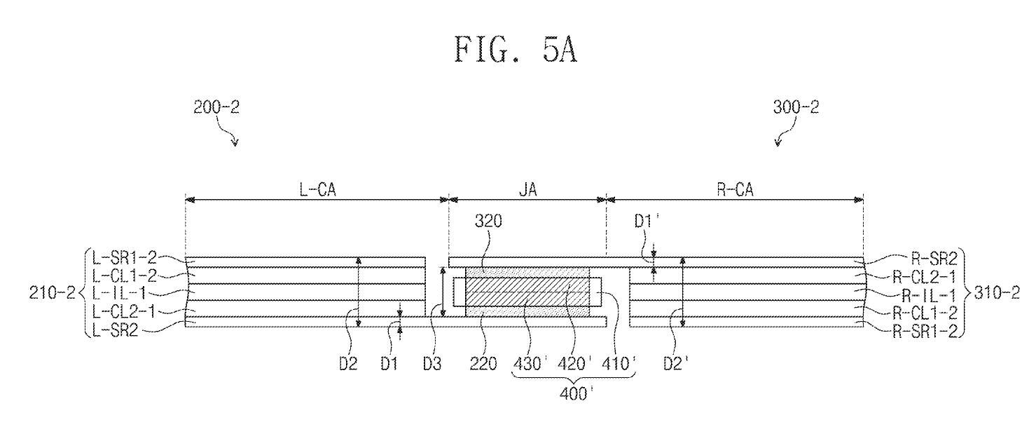

FIGS. 4A to 4C are cross-sectional views of a printed circuit board according to an embodiment of the inventive concept. FIGS. 4A to 4C exemplarily illustrate embodiments in which the first connecting pad parts 220 are disposed in different positions. Meanwhile, first printed circuit boards 200, 200-1, and 200-2 are exemplarily illustrated in FIGS. 4A to 4C for ease of description. Although not shown, since the description regarding the first printed circuit boards 200, 200-1, and 200-2 may be applied to the second printed circuit board 300 (refer to FIG. 1) in the same manner, redundant description will be omitted.

As illustrated in FIG. 4A, the first printed circuit board 200 may include a first board 210 and a first connecting pad part 220.

The first board 210 may include a first protective layer L-SR1, a first circuit layer L-CL1, a second circuit layer L-CL2, an insulation layer L-IL, and a second protective layer L-SR2.

The first protective layer L-SR1 may define a front surface of the first board 210. The first protective layer L-SR1 may be disposed on the first circuit layer L-CL1 while covering the first circuit layer L-CL1. The first protective layer L-SR1 may include a heat resistant resin. The first protective layer L-SR1 may include a polyimide (PI) film.

The first circuit layer L-CL1 may be disposed between the first protective layer L-SR1 and the insulation layer L-IL. For example, the first circuit layer L-CL1 may be disposed on a rear surface of the first protective layer L-SR1 and a top surface of the insulation layer L-IL. Although not shown, the first circuit layer L-CL1 may be electrically connected to the first connecting pad part 220 through a hole defined in the first protective layer L-SR1. The first circuit layer L-CL1 may include a conductive copper.

The insulation layer L-IL may be disposed between the first circuit layer L-CL1 and the second circuit layer L-CL2. For example, the insulation layer L-IL may be disposed on a rear surface of the first circuit layer L-CL1 and a top surface of the second circuit layer L-CL2. The insulation layer L-IL may insulate the first circuit layer L-CL1 from the second circuit layer L-CL2. The insulation layer L-IL may include an insulation polymer resin. The insulation polymer resin may include at least one selected from the group consisting of a polymer resin, a thermosetting resin, a thermoplastic resin, and a mixed resin thereof.

The second circuit layer L-CL2 may be disposed between the second protective layer L-SR2 and the insulation layer L-IL. For example, the second circuit layer L-CL2 may be disposed on a rear surface of the insulation layer L-IL and a top surface of the second protective layer L-SR2. Although not shown, the second circuit layer L-CL2 may be electrically connected to the first connecting pad part 220 through a hole defined in the second protective layer L-SR2 and the insulation layer L-IL. The second circuit layer L-CL2 may include a conductive copper.

The second protective layer L-SR2 may be disposed below the second circuit layer L-CL2 while covering the second circuit layer L-CL2. For example, the second protective layer L-SR2 may be disposed on a rear surface of the second circuit layer L-CL2. The second protective layer L-SR2 may include a heat resistant resin. The second protective layer L-SR2 may include a polyimide (PI) film.

The first connecting pad part 220 may be disposed on the first protective layer L-SR1. The first connecting pad part 220 may be electrically connected to one of the first circuit layer L-CL1 or the second circuit layer L-CL2. Here, although not shown, a connecting part passing through the first protective layer L-SR1 to connect the first connecting pad part 220 to the first circuit layer L-CL1 or a connecting part for passing through the first protective layer L-SR1 and the insulation layer L-IL to connect the first connecting pad part 220 to the second circuit layer L-CL2 may be further provided.

Referring to FIG. 4B, in a first printed circuit board 200-1, a first connecting pad part 220 may be disposed on the same layer as a first circuit layer L-CL1-1. Here, the first connecting pad part 220 is disposed between a first protective layer L-SR1-1 and an insulation layer L-IL.

Because at least a portion of the first protective layer L-SR1-1 is removed, the first connecting pad part 220 may be exposed to the outside. The first printed circuit board 200-1 may be easily connected to the second printed circuit board 300 (refer to FIG. 2) through the exposed first connecting pad part 220.

Meanwhile, in the embodiment, the first connecting pad part 220 is spaced apart from the first circuit layer L-CL1-1. However, an embodiment of the inventive concept is not limited thereto. For example, the first circuit layer L-CL1-1 and the first connecting pad part 220 may be connected to each other to have an integrated shape.

The first connecting pad part 220 may be electrically insulated from the first circuit layer L-CL1-1 and electrically connected to the second circuit layer L-CL2. Here, although not shown, a connecting part passing through the insulation layer L-IL to connect the second circuit layer L-CL2 to the first connecting pad part 220 may be further provided.

Referring to FIG. 4C, in a first printed circuit board 200-2, a first connecting pad part 220 may be disposed on the same layer as a second circuit layer L-CL2-1. Here, the first connecting pad part 220 is disposed between a first protective layer L-SR1-2 and a second protective layer L-SR2.

Because at least a portion of the first protective layer L-SR1-2 is removed, the first connecting pad part 220 may be exposed to the outside. The first printed circuit board 200-2 may be easily connected to the second printed circuit board 300 (refer to FIG. 2) through the exposed first connecting pad part 220.

Meanwhile, in the embodiment, the first connecting pad part 220 is spaced apart from the second circuit layer L-CL2-1. However, an embodiment of the inventive concept is not limited thereto. For example, the second circuit layer L-CL2-1 and the first connecting pad part 220 may be connected to each other to have an integrated shape.

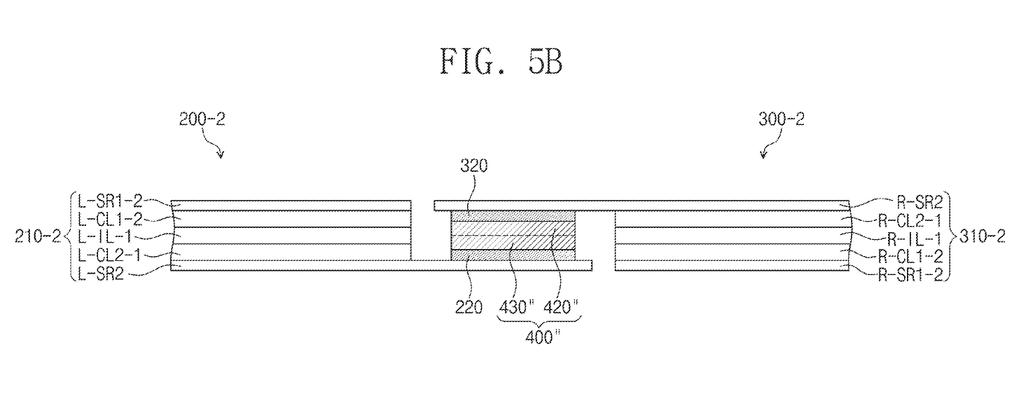

FIGS. 5A and 5B are cross-sectional views illustrating a state in which printed circuit boards are electrically connected according to an embodiment of the inventive concept. FIG. 5A exemplarily illustrates the first printed circuit board 200-2 in FIG. 4C and a second printed circuit board 300-2 having a structure corresponding to the first printed circuit board 200-2. Also, for ease of description, the connector is enlarged. Here, each of the layers of the printed circuit boards may be varied in thickness according to various embodiments.

Accordingly, the second printed circuit board 300-2 includes a first protective layer R-SR1-2, a first circuit layer R-CL1-2, an insulation layer R-IL-1, a second circuit layer R-CL2-1, a second protective layer R-SR2, and a first connecting pad part 320, which are respectively corresponded to the first protective layer L-SR1-2, the first circuit layer L-CL1-2, the insulation layer L-IL-1, the second circuit layer L-CL2-1, the second protective layer L-SR2, and the first connecting pad part 220 of the first printed circuit board 200-2. Hereinafter, redundant description will be omitted.

Meanwhile, FIGS. 5A and 5B include substantially the same components except for the connector. Hereinafter, connection between printed circuit boards according an embodiment of the inventive concept will be described with reference to FIGS. 5A and 5B.

As illustrated in FIG. 5A, a connector 400′ may include a base plate 410′, a first pad part 420′, and a second pad part 430′.

The base plate 410; may be rigid. Also, the base plate 410′ may be made of an insulation material. Meanwhile, the base plate may be made of a material having a melting point greater than that of each of the pad parts. For example, when the connection pad parts are made of copper (Cu), and the pad parts of the connector 400 is made of a material having a melting point less than copper, the base plate may be made of a material having a melting point greater than that of each of the pad parts.

The first pad part 420′ and the second pad part 430′ may be formed in a through hole which passes through the base plate 410′ and be connected to each other. The first pad part 420′ and the second pad part 430′ may form a flat surface with the base plate 410′. The first pad part 420′ and the second pad part 430′ are electrically and physically connected to the first connecting pad part 220 and the second connecting pad part 320. Accordingly, the first connecting pad part 220 and the second connecting pad part 320 may be stably connected through the connector 400′

Even after the connecting pad part of the first printed circuit board 200-2 and the connecting pad part of the second printed circuit board 300-2 are electrically connected, the base plate 410′ may be still remained between the first printed circuit board 200-2 and the second printed circuit board 300-2.

In the embodiment, each of the first printed circuit board 200-2 and the second printed circuit board 300-2 may include a circuit area L-CA and R-CA and a connection area JA. The connection area JA in which the first connecting pad part 220 and the second connecting pad part 320 are disposed may be an area in which the first printed circuit board 200-2 and the second printed circuit board 300-2 overlap each other. The circuit area L-CA and R-CA may be disposed adjacent to the connection area.

Each of the first printed circuit board 200-2 and the second printed circuit board 300-2 may have different thicknesses in the circuit area L-CA and R-CA and the connection area JA For example, the first printed circuit board may have a first thickness D1 in the connection area JA and a second thickness D2, which is different from the first thickness D1, in the circuit area L-CA. The second printed circuit board 300-2 may have a first thickness D1′ in the connection area JA and a second thickness D2′, which is different from the first thickness D1′, in the circuit area R-CA. The connector 400′ may have a third thickness D3.

In the embodiment, a sum of the thicknesses D1 and D1′ of the connection areas of the printed circuit boards and the thickness D3 of the connector may be equal to or less than the thickness D2 or D2′ of each of the printed circuit boards. In the embodiment, a sum of thicknesses D1, D1′, D3, the first connecting pad part 220 and the second connecting pad part 320 may be substantially equal to the thickness D2 or D2′. According to an embodiment of the inventive concept, although the first printed circuit board and the second printed circuit board overlap each other, the first printed circuit board and the second printed circuit board may be stably connected to each other without increasing the thickness.

Referring to FIG. 5B, in a connector 400″, a base plate may be removed unlike FIG. 5A. Since the base plate is relatively flexible and has flexibility, a portion or all of the base plate may be removed by heat/pressure generated in a thermal compression process. Accordingly, the base plate in FIG. 5B may not be remained, and all or a small amount of the base plate may be remained.

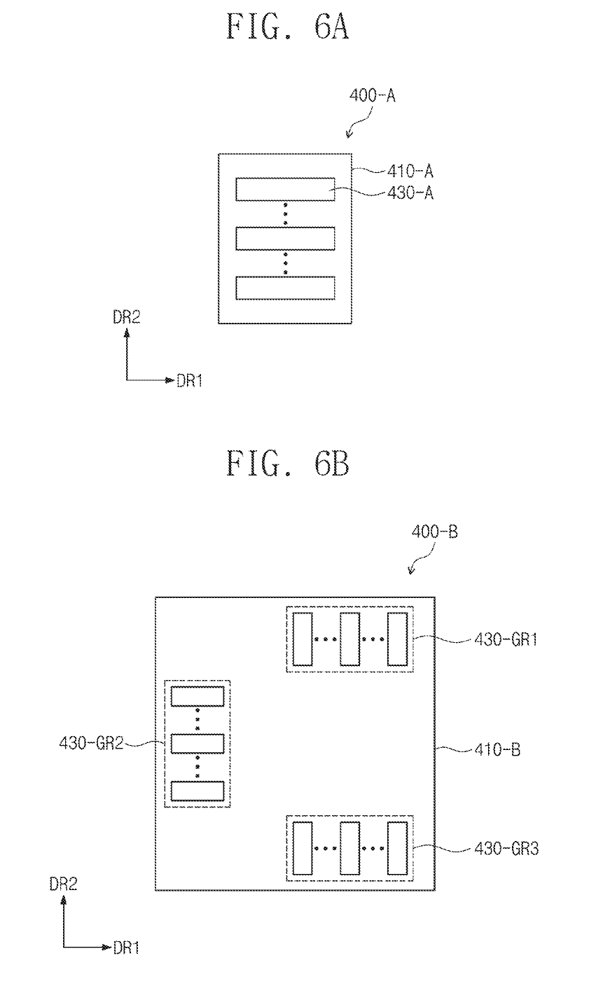

FIGS. 6A and 6B are plan views of a connector having a plurality of pads according to an embodiment. Definition regarding a pad surface in each embodiment may be the same as that in FIG. 3B.

A connector 400-A may include a base plate 410-A and a pad part 430-A.

The pad part 430-A may include a plurality of pads extending in a first direction DR1 and arranged in a second direction DR2 which is perpendicular to the first direction DR1. Although not shown, the pad part 430-A may define the same plane as one surface and the other surface of the base plate

410-A or may have one surface and the other surface, which protrude in a thickness direction of the base plate

410-A. However, an embodiment of the inventive concept is not limited to the shape and the arrangement type of the pad part. For example, the shape and the arrangement type of the pad part may be variously varied in correspondence to those of the connecting pad parts of the printed circuit board.

Also, as illustrated in FIG. 6B, a connector 400-B may include a base plate 410-B and a plurality of pad parts. Here, the pad part may be divided into a plurality of groups. The groups may include first to third groups 430-GR1, 430-GR2, and 430-GR3 that are respectively disposed on areas different from each other.

For example, the first group 430-GR1 may include connecting pads respectively extending in the second direction DR2 and arranged along the first direction DR1. The second group 430-GR2 may be spaced apart from the first group 430-GR1 in the second direction DR2. The second group 430-GR2 may include connecting pads arranged in correspondence to the pads of the first group 430-GR1. The third group 430-GR3 may be spaced apart from the first and second groups 430-GR1 and 430-GR2 in a direction parallel to the first direction DR1. The third group 430-GR3 may include connecting pads extending and arranged in a direction crossing the pads of each of the first and second groups 430-GR1 and 430-GR2.

The connectors according to an embodiment of the inventive concept may include connecting pads having various shapes and arranged in various types. The arrangement of the connecting pads may be designed so that the connecting pads are respectively easily connected to the pad parts provided on the printed circuit boards. As the connectors according to an embodiment of the inventive concept include various embodiments without being limited to one shape, the connectors may be easily connected between various printed circuit boards.

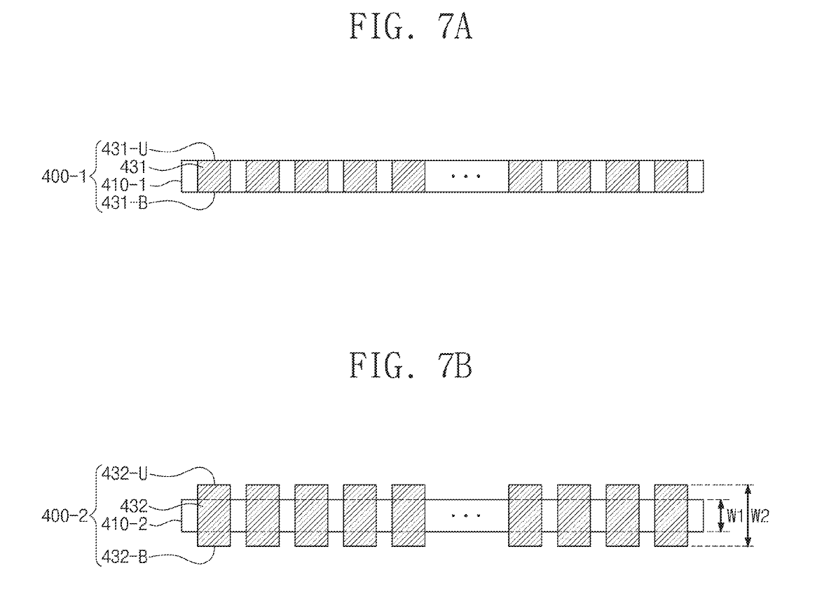

FIGS. 7A and 7B are cross-sectional views illustrating a connector having a pad formed in a through hole of a base plate according to an embodiment of the inventive concept.

A connector 400-1 may include a base plate 410-1 and a pad part 431.

The base plate 410-1 may provide insulation between a plurality of pad parts.

The pad part 431 may include a top pad surface 431-U and a bottom pad surface 431-B. The pad part 431 may be formed in a through hole which passes through the base plate 410-1.

The top pad surface 431-U may be defined as the pad part 431 exposed from one surface of the base plate 410-1. The bottom pad surface 431-B may be defined as the pad part 431 exposed from the other surface of the base plate 410-1.

The top pad surface 431-U may define the same plane as one surface of the base plate 410-1, and the bottom pad surface 431-B may defined the same plane as the other surface of the base plate 410-1. Accordingly, the connector 400-1 may include pad parts defined as the same plane as the one surface and the other surface of the base plate 410-1.

Alternatively, as illustrated in FIG. 7B, a connector 400-2 may include a base plate 410-2 and a pad part 432.

The base plate 410-2 may provide insulation between a plurality of pad parts and have a first thickness W1.

The pad part 432 may include a top pad surface 432-U and a bottom pad surface 432-B. The pad part 432 may be formed in a through hole which passes through the base plate 410-2.

The pad part 432 may pass through the base plate 410-2 to protrude in a thickness direction of one surface and the other surface of the base plate 410-2, thereby having a second thickness W2 that is greater than the first thickness W1.

The top pad surface 432-U may be defined as one surface of the pad part 432 protruding from one surface of the base plate 410-2 in the thickness direction, and the bottom pad surface 432-B may be defined as the other surface of the pad part 432 protruding from the other surface of the base plate 410-2 in the thickness direction Accordingly, the connector 400-2 may include a plurality of pad parts having the second thickness W2 in the thickness direction of the one surface and the other surface of the base plate 410-2.

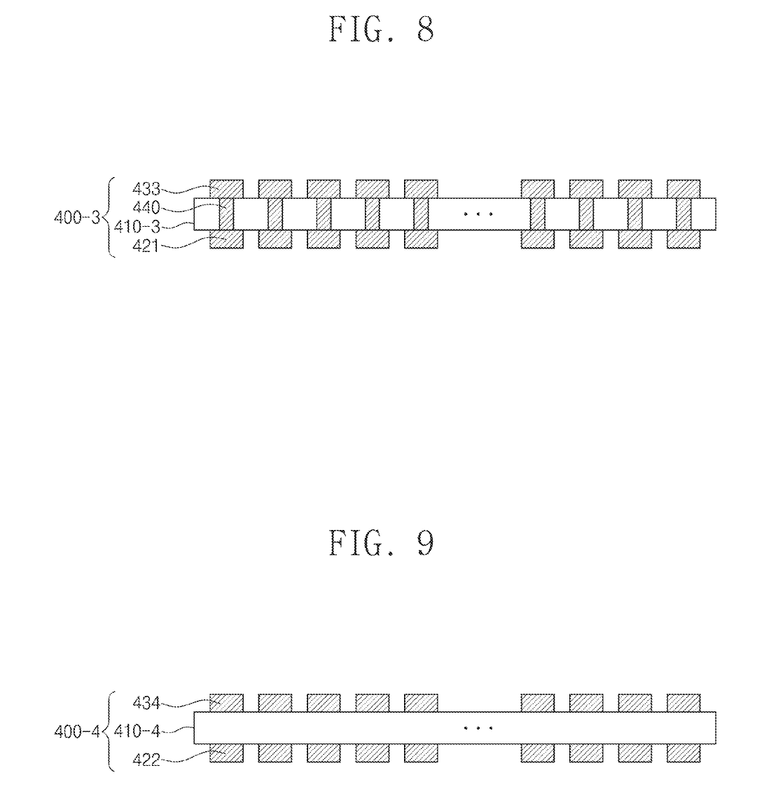

FIG. 8 is a cross-sectional view illustrating a connector having a passing-through pad according to an embodiment of the inventive concept.

A connector 400-3 may include a base plate 410-3, a first pad portion 421, a second pad portion 433, and a passing-through pad portion 440.

The first pad portion 421 may be disposed on one surface of the base plate 410-3. Also, the first pad portion 421 may overlap the second pad portion 433 in a plan view.

The second pad portion 433 may be disposed on the other surface of the base plate 410-3.

The passing-through pad portion 440 may pass through the base plate 410-3 to electrically connect the first pad portion 421 and the second pad portion 433 to each other, which overlap each other in a plan vie. The connector 400-3 includes the first pad portion 421, the second pad portion 433, and the passing-through pad portion 440 for convenience of description. The first pad portion 421, the second pad portion 433, and the passing-through pad portion 440 may be made of a single material and disposed on the base plate 410-3.

Accordingly, the connector 400-3 may include a plurality of first pad parts disposed on one surface of the base plate 410-3, a plurality of second pad parts disposed on the other surface of the base plate 410-3, and passing-through pad parts connecting the first pad part and the second pad part, which overlap each other in a plan view.

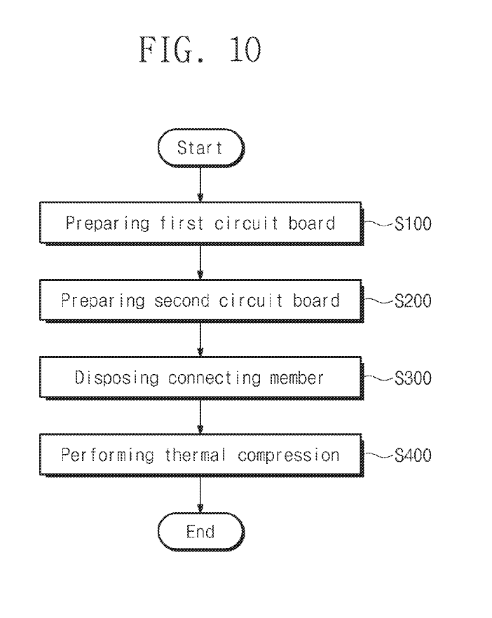

FIG. 9 is a cross-sectional view illustrating a connector having a pad disposed on one surface and the other surface of a base plate according to an embodiment of the inventive concept

A connector 400-4 may include a base plate 410-4, a first pad portion 422, and a second pad portion 434.

The first pad portion 422 may be disposed on one surface of the base plate 410-4. Also, the first pad portion 423 may overlap the second pad portion 434 in a plan view.

The second pad portion 434 may be disposed on the other surface of the base plate 410-4.

Accordingly, the connector 400-4 may include a plurality of first pad parts disposed on the one surface of the base plate 410-3 and a plurality of second pad parts disposed on the other surface of the base plate 410-3.

Since the base plate 410-4 is relatively flexible and has flexibility, a portion or all of the base plate may be removed by heat/pressure generated in a thermal compression process.

In the embodiment, the first pad portion 422 and the second pad portion 434 may be electrically connected to each other. For example, as the base plate 410-4 is firstly removed in the thermal compression process because the base plate 410-4 has a melting point less than that of each of the first pad portion 422 and the second pad portion 434, the first pad portion 422 and the second pad portion 434 may be electrically connected to each other. This will be described later in detail.

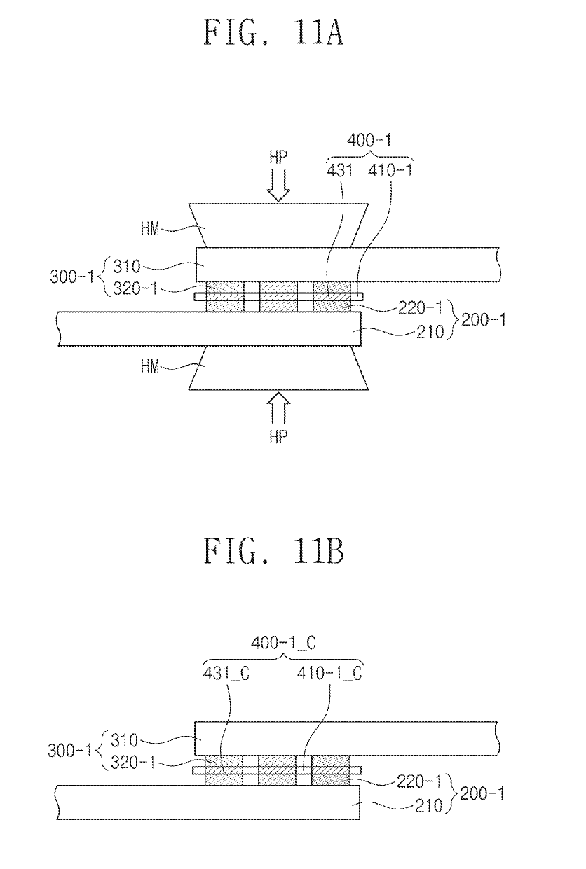

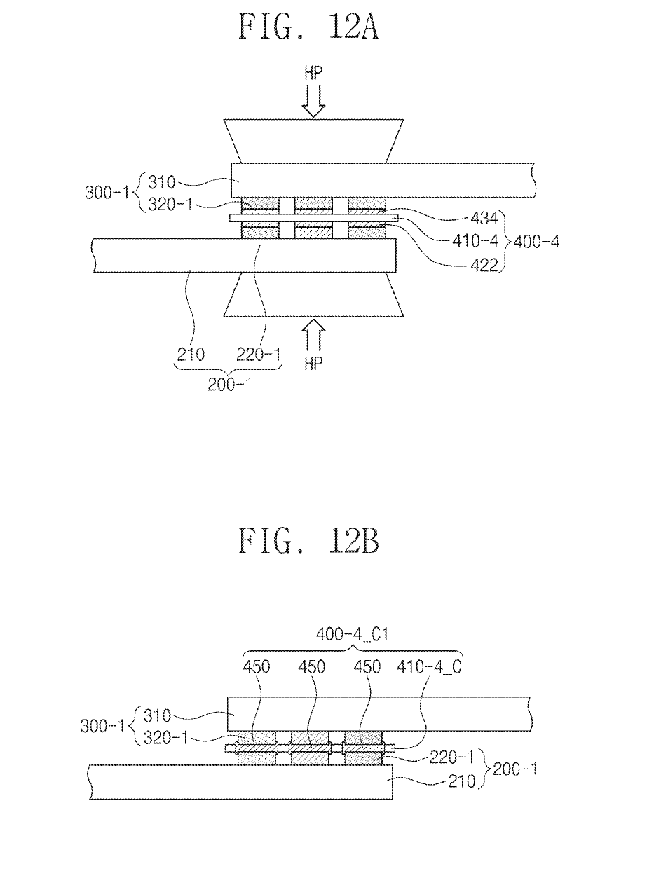

FIG. 10 is a flowchart of a method of manufacturing a display device according to an embodiment of the inventive concept. FIGS. 11A and 11B illustrate a process of performing a thermal compression on printed circuit boards according to an embodiment of the inventive concept. Thus, the method of manufacturing a display device according to an embodiment of the inventive concept will be described with reference to FIG. 11B. In the embodiment, the connector 400-1 in FIG. 7A is exemplarily illustrated as a connector.

The method of manufacturing a display device may include a step S100 of providing a first printed circuit board, a step S200 of providing a second printed circuit board, a step S300 of providing a connector, and a step S400 of performing a thermal compression.

Referring to FIG. 11a, in the step S100 of providing a first printed circuit board, a first printed circuit board 200-1 including a first board 210 and a plurality of first connecting pad parts 220-1 is provided. Here, a pad surface defined on a first connecting pad part 220-1 may face an upper side (front surface).

In the step S200 of providing a second printed circuit board, a second printed circuit board 300-1 including a second board 310 and a plurality of second connecting pad parts 320-1, which corresponds to the first printed circuit board 200-1, is provided. Here, a pad surface defined on a second connecting pad part 320-1 may face a lower side (rear surface).

In the step S300 of providing a connector, a connector 400-1 including a base plate 410-1 and a plurality of pad parts 431 may be provided. The connector 400-1 may include a base plate 410-1 a pad part 431 formed through the base 410-1. The pad part 431 passing through the base plate 410-1 includes a plurality of pad parts, and the exposed plurality of pad parts may have one surface and the other surface opposing each other, which form the same plane as one surface and the other surface of the base plate 410-1.

In the step S400 of performing thermal compression, heat and pressure may be provided to connect the first printed circuit board 200-1 to the second printed circuit board 300-1. The heat and the pressure may be provided by a thermal compression device HM. The thermal compression instrument HM may be disposed in correspondence to a portion at which the first printed circuit board 200-1 and the second printed circuit board 300-1 are bonded. The thermal compression instrument HM generates plastic flow on a bonding portion by applying predetermined thermal compression HP. Accordingly, as an oxide film is broken to activate metal surfaces, the activated metal surfaces contact each other and are bonded to each other.

In the step S400 of performing thermal compression, the connector 400-1 may be deformed into a deformed connector 400-1_C. The deformed connector 400-1_C may be generated by the above-described plastic flow.

In detail, in the step S400 of performing thermal compression, the heat may have a temperature range that is equal to or less than a melting point of each of the first connecting pad part 220-1 and the second connecting pad part 320-1 and equal to or greater than a melting point of the pad part 431.

The base plate 410-1 may be made of a material having a melting point greater than that of the pad part 431. Accordingly, in the step S400 of performing thermal compression, although the pad parts are deformed, the base plate 410-1 may stably maintain a shape thereof. Also, the base plate 410 may be made of a rigid material. Accordingly, as illustrated in FIG. 11B, after the step S400 of performing thermal compression, the base plate 410-1_C may not be removed to be remained in a state in which the first printed circuit board 200-1 and the second printed circuit board 300-1 are electrically connected to each other by the connector 400-1_C.

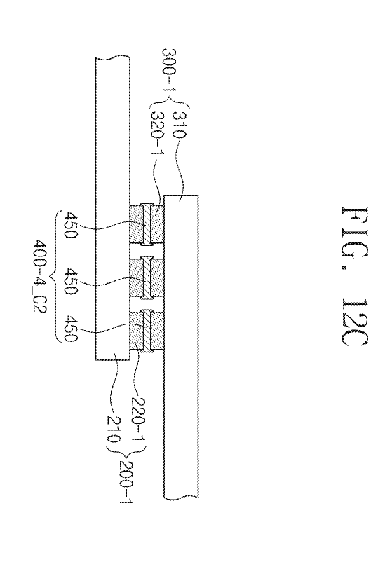

FIGS. 12A to 12C are cross-sectional views illustrating a step of performing thermal compression on printed circuit boards according to an embodiment of the inventive concept. FIGS. 12A to 12C illustrate an embodiment of the step S400 of performing thermal compression in FIG. 10A. Meanwhile, FIGS. 12A to 12C illustrate first and second circuit boards corresponding to the embodiments in FIGS. 11A and 11B. Hereinafter, redundant description will be omitted.

As illustrated in FIG. 12A, a connector 400-4 may include a base plate 410-4, a first pad portion 434, and a second pad portion 422.

The base plate 410-4 may have a melting point less than that of each of the first pad portion 434, and the second pad portion 422. The base plate 410-4 may be made of a flexible material.

The first pad portion 434 may be disposed on one surface of the base plate 410-4. Also, the first pad portion 434 may overlap the second pad portion 422 in a plan view. The second pad portion 422 may be disposed on the other surface of the base plate 410-4.

As illustrated in FIG. 12B, a first pad portion 434 and a second pad portion 422 may pass through a base plate 410-4_C to provide an integrated pad part 450 having an integrated shape by predetermined thermal compression HP. Accordingly, a connector 400-4_C1 may include integrated pad portions and the base plate of which a portion is deformed in shape. In virtue of this, the first printed circuit board 200-1 and the second printed circuit board 300-1 may be electrically connected through the integrated pad part 450.

As illustrated in FIG. 12C, when predetermined thermal compression HP greater than the thermal compression HP in FIG. 12B is applied, the base plate 410-4_C1 of which a portion is deformed in shape may be removed after the first printed circuit board 200-1 and the second printed circuit board 300-1 are electrically connected. Accordingly, a connector 400-4_C2 may include only integrated pad parts without the base plate 410-4_C1 of which a portion is deformed in shape.

According to the embodiments of the inventive concept, the thermal compression process is used to electrically connect the divided printed circuit boards of a large-sized display device. Here, the thermal compression process is performed while the connector is disposed between the divided printed circuit boards. Accordingly, in virtue of the thermal compression process, as the connector for connecting printed circuit boards which are divided and the additional member for connecting the same are unnecessary, the process may be simplified and the costs may be reduced. Furthermore, in virtue of the thermal compression process, electric characteristics of the printed circuit board may increase, and compression quality thereof may be maintained.

Hereinabove, the embodiment is disclosed in the drawings and the specification. While specific terms were used, they were not used to limit the meaning or the scope of the present inventive concept described in claims, but merely used to explain the present inventive concept. Accordingly, a person having ordinary skill in the art will understand from the above that various modifications and other equivalent embodiments are also possible. Hence, the real protective scope of the present inventive concept shall be determined by the technical scope of the accompanying claims.

What is claimed is:

1. A display device comprising:
a display panel configured to display an image;
a first circuit board electrically connected to the display panel and comprising a first connecting pad part;
a second circuit board electrically connected to the display panel and comprising a second connecting pad part overlapping the first connecting pad part; and
a connector disposed between the first circuit board and the second circuit board to electrically connect the first connecting pad part and the second connecting pad part,
wherein the connector comprises:
a base plate; and
a pad part comprising a first pad surface exposed from one surface of the base plate and a second pad surface exposed from the other surface of the base plate, and
the first pad surface and the second pad surface overlap each other in a plan view.

2. The display device of claim 1, wherein the pad part passes through the one surface and the other surface of the base plate and comprises a pad.

3. The display device of claim 2, wherein the first pad surface and the one surface of the base plate define the same plane, and the second pad surface and the other surface of the base plate define the same plane.

4. The display device of claim 2, wherein, in the connector,
the first pad surface protrudes from the one surface of the base plate in a thickness direction of the base plate, and
the second pad surface protrudes from the other surface of the base plate in the thickness direction of the base plate.

5. The display device of claim 2, wherein the base plate comprises a material that is rigid and has a melting point greater than that of the pad, and
the pad comprises a material having a melting point less than that each of the first connecting pad part and the second connecting pad part.

6. The display device of claim 1, wherein each of a first circuit board and a second circuit board comprises:
a first circuit layer;
a second circuit layer disposed on a rear surface of the first circuit layer;
an insulation layer disposed between the first circuit layer and the second circuit layer;
a first protective layer disposed on a front surface of the first circuit layer; and
a second protective layer disposed on a rear surface of the second circuit layer.

7. The display device of claim 6, wherein each of the first connecting pad part and the second connecting pad part is disposed on the first protective layer and electrically connected to the first circuit layer or the second circuit layer.

8. The display device of claim 6, wherein each of the first connecting pad part and the second connecting pad part is disposed on the same layer as the first circuit layer or the second circuit layer and exposed from the first protective layer.

9. The display device of claim 6, wherein each of the first circuit board and the second circuit board include a connection area in which each of the first connecting pad part and the second connecting pad part is disposed and a circuit area disposed adjacent to the connection area,
the connection area has a thickness less than that of the circuit area, and
a sum of a thickness of the connection area of the first circuit board, a thickness of the connection area of the second circuit board, and a thickness of the connector is equal to or less than a thickness of each of the circuit areas.

10. A connector comprising:
a base plate; and
a pad part comprising a first pad surface exposed from one surface of the base plate and a second pad surface exposed from the other surface of the base plate, and
the first pad surface and the second pad surface overlap each other in a plan view.

11. The connector of claim 10, wherein the pad part comprises a pad passing through one surface and the other surface of the base plate.

12. The connector of claim 11, wherein the first pad surface and the one surface of the base plate define the same plane, and the second pad surface and the other surface of the base plate define the same plane.

13. The connector of claim 11, wherein the first pad surface protrudes from the one surface of the base plate in a thickness direction of the base plate, and
the second pad surface protrudes from the other surface of the base plate in the thickness direction of the base plate.

14. The connector of claim 11, wherein the base is rigid,
the base comprises a material having a melting point greater than that of each of the first and second pad surfaces, and
each of the first and second pad surfaces comprises a material having a melting point less than that of copper (Cu).

15. The connector of claim 10, wherein the pad part comprises a pad, and
the pad comprises:
a first pad disposed on the one surface of the base plate to comprise the first pad surface; and
a second pad disposed on the other surface of the base plate to comprise the second pad surface.

16. The connector of claim 14, further comprising a passing-through pad portion connecting the first and second pads while overlapping the first and second pads in a plan view.

17. The connector of claim 14, wherein the base plate is flexible,
the base plate comprises a material having a melting point less than that of each of the first and second pads, and
each of the first and second pads comprises a material having a melting point less than that of copper (Cu).

18. A method of manufacturing a display device, the method comprising:
providing a first circuit board comprising a first connecting pad part;
providing a second circuit board comprising a second connecting pad part configured to overlap the first connecting pad part;
providing a connector configured to electrically connect the first connecting pad part to the second connecting pad part and disposed between the first and second circuit boards; and
performing thermal compression on the first and second connecting pad parts and the connector so that the first and second circuit boards are electrically connected to each other,
wherein the connector comprises:
a base plate; and
a pad part comprising a first pad surface exposed from one surface of the
base plate and a second pad surface exposed from the other surface of the base plate, and
the first and second pad surfaces overlap each other in a plan view.

19. The method of claim 18, wherein, when the first and second circuit boards are connected to each other, the base plate is remained between the pad parts in an alternating manner.

20. The method of claim 18, wherein, when the first and second circuit boards are connected to each other, heat greater than a melting point of the base plate is provided.
